(19) United States
(12) Patent Application Publication
(10) Pub. No.: US 2025/0393295 A1
(43) Pub. Date: Dec. 25, 2025

(54) SEMICONDUCTOR DEVICE

(71) Applicant: ROHM CO., LTD., Kyoto-shi (JP)

(72) Inventors: Hiroaki SAWAOKA, Kyoto (JP); Kazumasa NISHIO, Kyoto (JP); Kosaku ADACHI, Kyoto (JP)

(21) Appl. No.: 19/238,922

(22) Filed: Jun. 16, 2025

(30) Foreign Application Priority Data
Jun. 25, 2024 (JP) 2024-102132

(51) Int. Cl. H10D 84/00; H10D 1/47; H10D 1/68

(52) U.S. Cl. CPC H10D 84/206; H10D 1/47; H10D 1/692

(57) ABSTRACT

A semiconductor device includes: an insulating layer formed on a semiconductor substrate; a first resistor embedded in the insulating layer; a second resistor embedded in the insulating layer and connected in series with the first resistor; and a first capacitor comprising: a first upper electrode formed on the insulating layer and electrically connected to one end of the first resistor; and a first lower electrode formed in the insulating layer and electrically connected to one end of the second resistor, wherein the first lower electrode is electrically connected to the second resistor and is electrically connected to a reference electrode formed on the insulating layer.

### CROSS-REFERENCE TO RELATED APPLICATIONS

The present invention claims priority under 35 U.S.C. § 119 to Japanese Patent Application No. 2024-102132, filed on Jun. 25, 2024. The entire contents of the above-identified application are hereby incorporated by reference.

### TECHNICAL FIELD

The present disclosure relates to a semiconductor device.

### BACKGROUND

International Publication No. WO 2023/085026 discloses a semiconductor device including a plurality of resistor elements.

### BRIEF DESCRIPTION OF THE DRAWINGS

FIG. 1 is a plan view of a semiconductor package on which a high voltage detection device is mounted.

FIG. 2 is a circuit diagram of a high voltage detection device.

FIG. 3A is a circuit diagram of a first example of a resistor and FIG. 3B is a circuit diagram of a second example of the resistor.

FIG. 4 is a circuit diagram of a resistor in the vicinity of the reference electrode.

FIG. 5 is a diagram showing an example configuration of a resistor.

FIG. 6 is a diagram showing the connection relationship between the resistor and the electrode.

FIG. 7A is a vertical sectional view of the resistor along the arrows A-A in FIG. 6 and FIG. 7B is a vertical sectional view of the resistor along the arrows B-B in FIG. 6.

FIG. 8 is a circuit diagram for experiments.

FIG. 9 is a graph showing the relationship between the capacitance (fF) of the first capacitor C1 in the circuit shown in FIG. 8 and the current I_{R} (μA) flowing through one resistor element in various resistors.

FIG. 10 is a plan view showing the configuration of a resistor with dummy wiring.

FIG. 11 is a vertical sectional view of the resistor along the arrows A-A in FIG. 10.

FIG. 12 is a plan view showing an example configuration of a resistor chip.

### DETAILED DESCRIPTION

The various exemplary embodiments will be described in detail with reference to the drawings below. In the drawings, the same reference numerals will be used for the same or equivalent parts, and redundant explanations will be omitted.

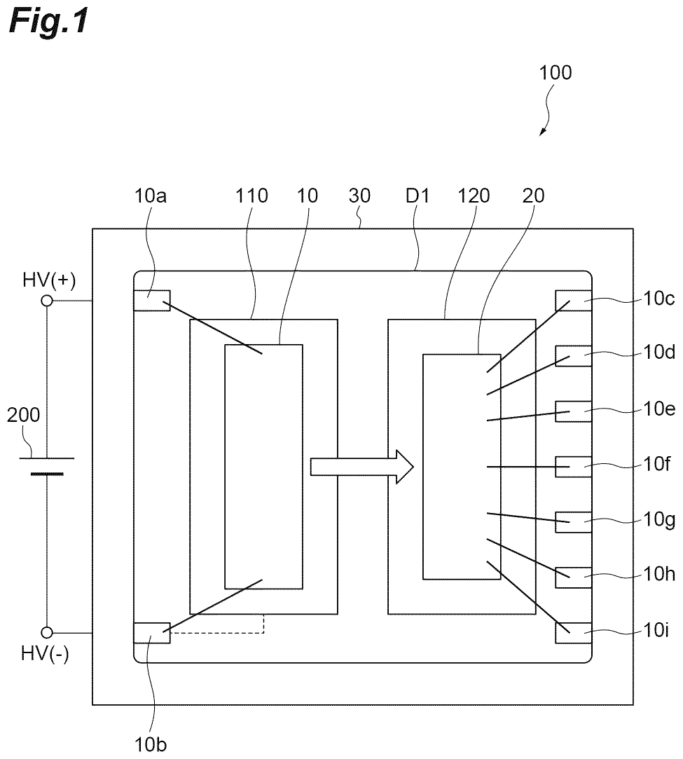

FIG. 1 is a plan view of a semiconductor package 100 on which a high voltage detection device is mounted.

In this figure, the state with the upper lid member removed is shown.

The semiconductor package 100 includes a case 30 having a recess D1. The case 30 is made of an insulating material such as resin or ceramic. The semiconductor package 100 includes a resistor chip 10 (semiconductor device) disposed on a first die pad 110 in the recess D1, and an amplifier chip 20 (semiconductor device) disposed on a second die pad 120 in the recess D1. The opening of the recess D1 of the semiconductor package 100 is sealed by a lid member (not shown), and the inside of the recess D1 is made into a sealed space. The lid member can be made of an insulating material such as resin; the recess D1 may be filled with a gas, or an insulating material may be filled therein. Appropriate potentials such as ground potential may be applied to the first die pad 110 and the second die pad 120 via a lead frame. It is also possible to set, for instance, the potential of the first die pad 110 to a high potential, depending on necessity.

An output voltage of the resistor chip 10 is input to the amplifier chip 20. The amplifier chip 20 outputs a voltage corresponding to the detected voltage.

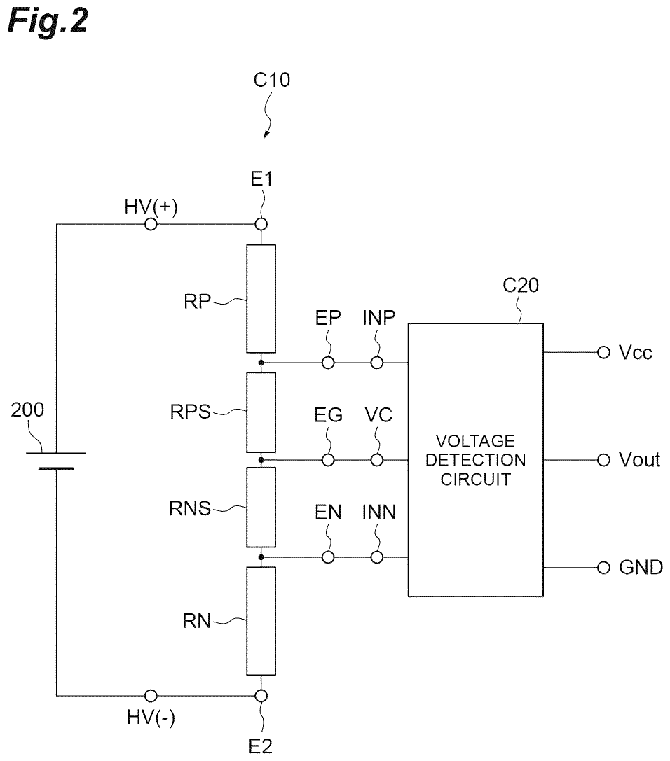

A positive terminal of a battery 200 is electrically connected to a first inner lead 10a and connected via bonding wires to a first electrode El (see FIG. 2) of the resistor chip 10. A negative terminal of the battery 200 is electrically connected to a second inner lead 10b and is connected to a second electrode E2 (see FIG. 2) of the resistor chip 10 via a bonding wire.

Each terminal of the amplifier chip 20 can be connected via a bonding wire to a third inner lead 10c, a fourth inner lead 10d, a fifth inner lead 10e, a sixth inner lead 10f, a seventh inner lead 10g, an eighth inner lead 10h, and a ninth inner lead 10i.

For example, the power supply voltage Vcc is applied to the third inner lead 10c and is input to the amplifier chip 20. The ground potential GND is applied to the ninth inner lead 10i and is input to the amplifier chip 20. The sixth inner lead 10f can output the output voltage Vout. From the fourth inner lead 10d, a monitor signal corresponding to the potential of a first output electrode EP (see FIG. 2) can be output. From the eighth inner lead 10h, a monitor signal corresponding to the potential of a second output electrode EN (see FIG. 2) can be output. The fifth inner lead 10e and the seventh inner lead 10g may be used for other purposes as necessary.

FIG. 2 is a circuit diagram of a high voltage detection device. The high voltage detection device includes a resistor circuit C10 (voltage divider circuit) and a voltage detection circuit C20. The resistor chip 10 described above includes the resistor circuit C10. The amplifier chip 20 includes the voltage detection circuit C20. A first input terminal HV(+) of the resistor circuit C10 is electrically connected to the positive terminal of the battery 200. A second input terminal HV(−) of the resistor circuit C10 is electrically connected to the negative terminal of the battery 200. The first input terminal HV(+) is electrically connected to a first electrode E1 (electrode pad). The second input terminal HV(−) is electrically connected to a second electrode E2 (electrode pad).

The resistor circuit C10 includes a first high-resistance part RP (a first resistor), a first low-resistance part RPS, a second low-resistance part RNS, and a second high-resistance part RN (a second resistor). Between the first electrode E1 and the second electrode E2, the first high-resistance part RP, the first low-resistance part RPS, the second low-resistance part RNS, and the second high-resistance part RN are connected in series in this order. The first high-resistance part RP and the second high-resistance part RN function to reduce the high voltage, and each of them has a relatively large resistance value. The first low-resistance part RPS and the second low-resistance part RNS function to detect the voltage, and each has a relatively low resistance value as compared to the high-resistance parts.

An exemplary value of the resistance of one high-resistance part is 500 MΩ, but it may be set to 1 MΩ or more and 1000 MΩ or less. The resistance value of the high-resistance part may also be set to 100 MΩ or more and 800 MΩ or less. The resistance value of the high-resistance part may also be set to 300 MΩ or more and 600 MΩ or less. The resistance value may have the capability to withstand high voltage and enable voltage detection.

The resistance value of one low-resistance part (RPS or RNS) is at or below K % of the resistance value of the high-resistance part. Exemplary values for K % include 5%, 3%, 1%, 0.5%, 0.3%, 0.1%, 0.05%, or 0.01%, and the resistance of the low-resistance part may, for instance, be set to 0.01 MΩ to 10 MΩ.

A connection point between the first high-resistance part RP and the first low-resistance part RPS is electrically connected to the first output electrode EP (electrode pad). A connection point between the second high-resistance part RN and the second low-resistance part RNS is electrically connected to the second output electrode EN (electrode pad). A reference electrode EG (electrode pad) is electrically connected between the first low-resistance part RPS and the second low-resistance part RNS.

Since the resistor circuit C10 is a voltage divider circuit, it is possible to obtain a voltage corresponding to the resistance value between selected two nodes within the resistor circuit C10. The first output electrode EP is electrically connected to a first input terminal INP of the voltage detection circuit C20. The second output electrode EN is electrically connected to a second input terminal INN of the voltage detection circuit C20. The reference electrode EG is electrically connected to a reference terminal VC of the voltage detection circuit C20. The potential of the reference terminal VC can be set to, for example, the ground potential. The voltage detection circuit C20 can output the output voltage Vout. The output voltage Vout can be the total of the magnitude of the first potential difference between the first input terminal INP and the reference terminal VC, and the magnitude of the second potential difference between the second input terminal INN and the reference terminal VC. The voltage detection circuit C20 may be provided with a source follower (amplifier) to amplify the voltage input from the input terminals and may include a differential amplifier circuit to obtain the sum of the magnitudes of the input voltages. The voltage detection circuit C20 includes an input terminal for a power supply voltage Vcc for operating its internal circuit, and an input terminal for setting the ground potential GND.

The resistor circuit C10 can include dummy resistors.

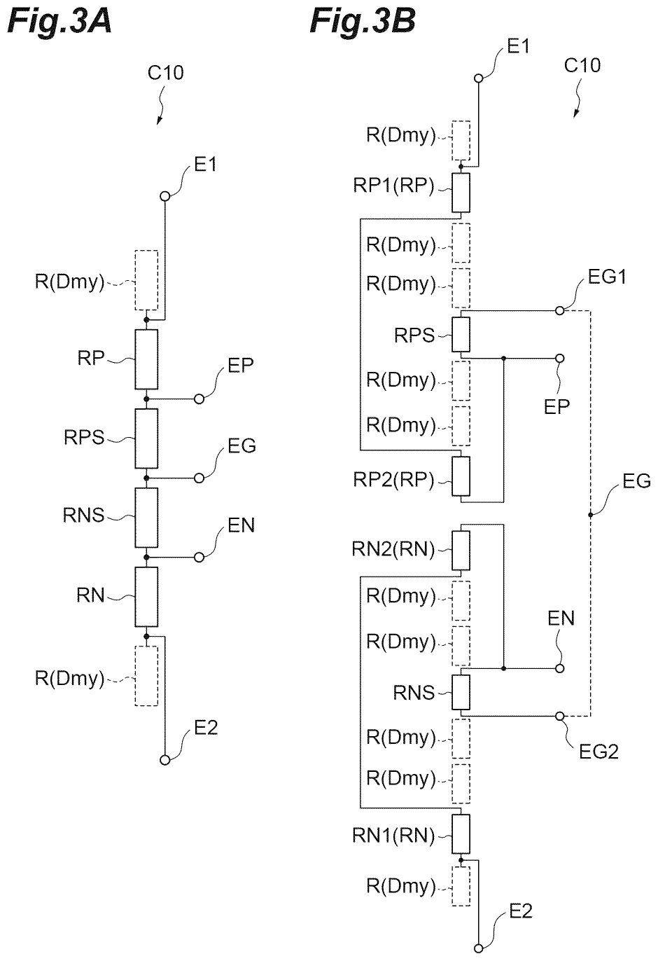

FIG. 3A is a circuit diagram of a first example of a resistor and FIG. 3B is a circuit diagram of a second example of the resistor.

In the resistor circuit C10 of FIG. 3A, one end of a dummy resistor R(Dmy) is electrically connected to the input side of the first high-resistance part RP. A dummy resistor R(Dmy) is electrically connected to the input side of the second high-resistance part RN. The dummy resistor need not necessarily be electrically connected to the resistor. For example, resistors at each end of a resistor chip may have slightly different resistance characteristics compared to resistors near the center part of the chip. By handling such a resistor as a dummy resistor, detection accuracy may be improved.

The resistor circuit C10 of FIG. 3B has a modified configuration of the circuit of the first example. In this example, the first high-resistance part RP is composed of a high-resistance part RP1 and a high-resistance part RP2 connected in series, and the second high-resistance part RN is composed of a high-resistance part RN1 and a high-resistance part RN2 connected in series. Moreover, the reference electrode EG is split into a first reference electrode EG1 and a second reference electrode EG2, and these electrodes may be electrically connected on the voltage detection circuit side. Furthermore, compared with the circuit of the first example, one or more dummy resistors R(Dmy) are also provided between each of the resistor parts.

A dummy resistor is a resistor that does not conduct current under normal conditions and is provided for maintaining electrical equivalence in the resistor circuit C10, for maintaining electrical stability, or for reducing error factors in resistor formation during manufacturing processes. The circuit configuration of the high voltage detection device is not limited to the examples provided and may be modified in terms of the shape and arrangement of the resistors as long as the basic voltage detection function can be achieved.

The high voltage detection device described above can be housed within a single semiconductor package as explained. The functions of each circuit can also be split between the resistor chip and the amplifier chip and mounted within the package. It is also possible to move some circuit components to either chip, or to integrate them into a single chip.

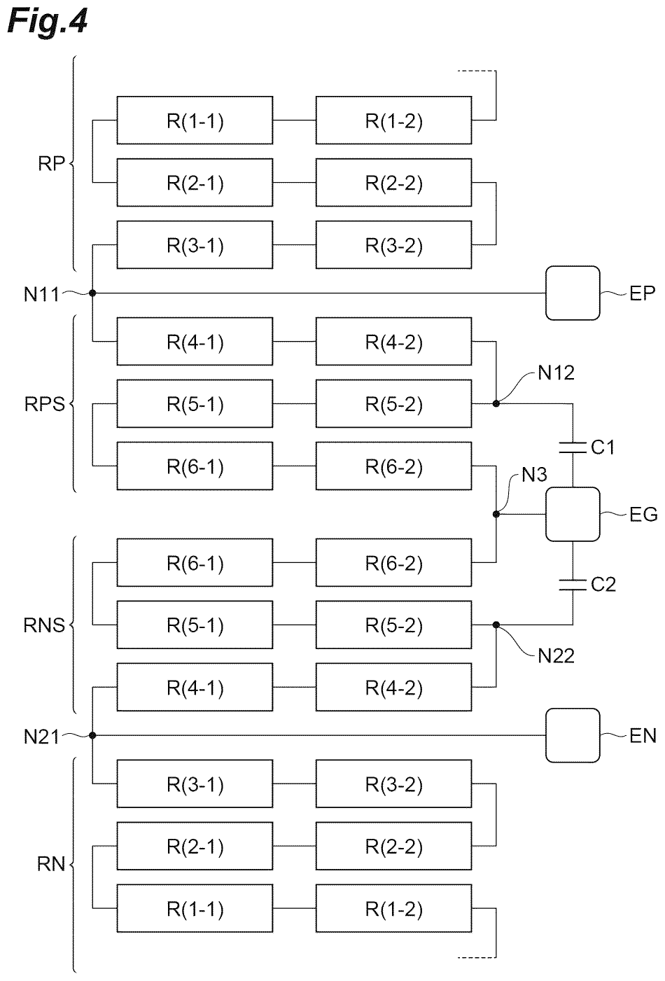

FIG. 4 is a circuit diagram of a resistor in the vicinity of the reference electrode.

The first high-resistance part RP on the side to which a positive high potential is applied includes a first resistor R(1), a second resistor R(2), and a third resistor R(3) connected in series. One resistor is composed of at least two resistor elements (resistors, resistor layers) connected in series. For example, the first resistor R(1) is composed of two resistor elements (R(1-1) and R(1-2)) connected in series. Similarly, the kth resistor R(k) is composed of two resistor elements (R(k-1) and R(k-2)) connected in series (k is a natural number).

The second high-resistance part RN on the side to which a negative high potential is applied includes a first resistor R(1), a second resistor R(2), and a third resistor R(3) connected in series.

The first low-resistance part RPS includes a fourth resistor R(4), a fifth resistor R(5), and a sixth resistor R(6) connected in series. Similarly, the second low-resistance part RNS includes a fourth resistor R(4), a fifth resistor R(5), and a sixth resistor R(6) connected in series.

A node (N11) between the first high-resistance part RP and the first low-resistance part RPS is connected to the first output electrode EP. A first node N12 between the resistor R(4) and the resistor R(5) in the first low-resistance part RPS is connected to one electrode of the first capacitor C1. The other electrode of the first capacitor C1 is electrically connected to the reference electrode EG.

A node (N21) between the second high-resistance part RN and the second low-resistance part RNS is connected to the second output electrode EN. A second node N22 between the resistor R(4) and the resistor R(5) in the second low-resistance part RNS is connected to one electrode of the second capacitor C2. The other electrode of the second capacitor C2 is electrically connected to the reference electrode EG.

The reference electrode EG is electrically connected to a node N3 between the resistor R(6) in the first low-resistance part RPS and the resistor R(6) in the second low-resistance part RNS. In other words, the reference electrode EG is electrically connected to one end of the resistor R(6) in the first low-resistance part RPS and one end of the resistor R(6) in the second low-resistance part RNS.

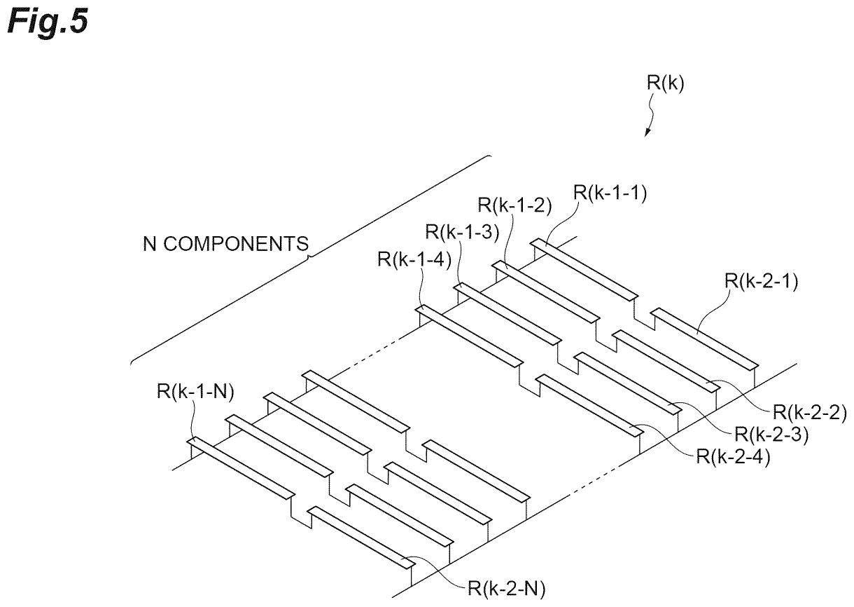

FIG. 5 is a diagram showing an example configuration of a resistor.

In the first low-resistance part RPS and the second low-resistance part RNS, one resistor R(k) includes a first group of N resistor elements (R(k-1-1) to R(k-1-N)) and a second group of N resistor elements (R(k-2-1) to R(k-2-N)) connected in series, and the resistor composed of a pair of resistor elements (R(k-1-n), R(k-2-n)) (n is a natural number) can be connected in parallel. By connecting in parallel, the resistance value of the resistor R(k) can be reduced. Such a parallel connection configuration is useful in the low-resistance part but can also be used in the high-resistance part. Note that via electrodes are connected to the lower surfaces of both ends of each resistor element, and buried electrodes are arranged below the via electrodes, and the adjacent resistor elements are electrically connected by these buried electrodes.

For example, the resistor (R(5): RPS) includes a plurality of resistor elements (resistors) connected in parallel, the resistor (R(6): RPS) includes a plurality of resistor elements (resistors) connected in parallel, the resistor (R(5): RNS) includes a plurality of resistor elements (resistors) connected in parallel, and the resistor (R(6): RNS) includes a plurality of resistor elements (resistors) connected in parallel. In the low-resistance part, by connecting a plurality of resistor elements in parallel, the resistance value can be reduced, and the voltage detection accuracy can be improved.

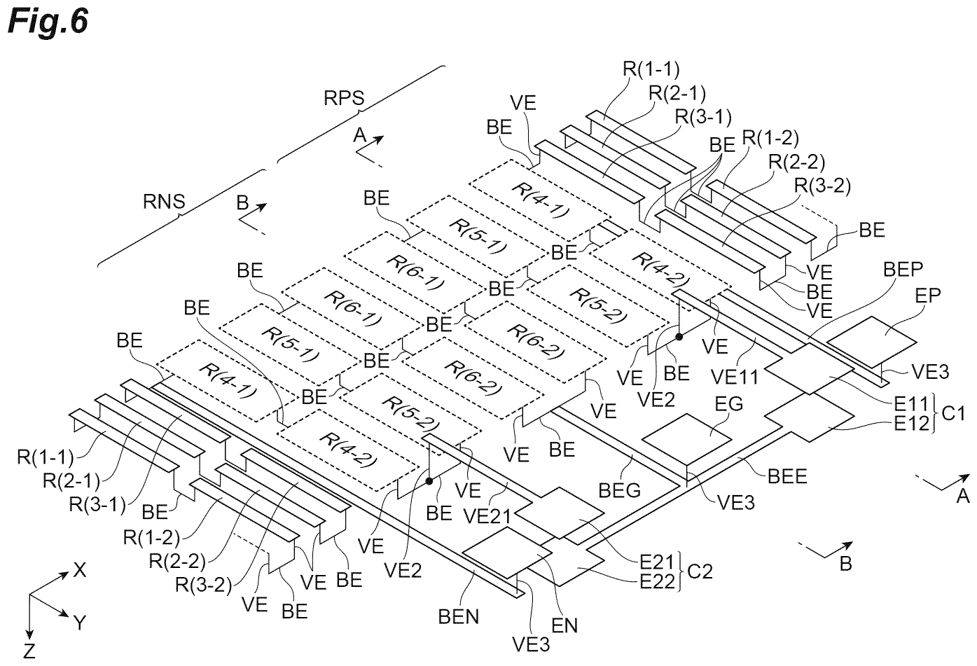

FIG. 6 is a diagram showing the connection relationship between the resistor and the electrode. In this figure, an XYZ three-dimensional orthogonal coordinate system is shown. The depth direction of the semiconductor substrate is the Z-axis direction, the direction perpendicular to the Z-axis and along which individual resistor elements extend is the Y-axis direction, and the direction perpendicular to both the Z-axis and the Y-axis is the X-axis direction.

The resistor R(k) includes resistor elements (R(k-1), R(k-2)), and the resistor R indicates any resistor R(k). Adjacent resistor elements along the Y-axis direction are connected in series by via electrodes VE and buried electrodes BE arranged directly below both ends. Adjacent resistor elements along the X-axis direction are connected by respective via electrodes VE arranged directly below their respective ends and buried electrodes BE connected to these via electrodes VE.

A connection point between the resistor element (resistor R(4-1)) in the first low-resistance part RPS and the resistor element (R(3-1)) in the first high-resistance part, in other words, a buried electrode BE electrically connecting these ends, is connected to a first wiring BEP extending along the Y-axis direction. The end of the first wiring BEP is electrically connected to the first output electrode EP via a via electrode (VE3) formed thereon. The first wiring BEP is formed in the same layer as the buried electrode BE.

A connection point between the resistor element (resistor R(4-1)) in the second low-resistance part RNS and the resistor element (R(3-1)) in the second high-resistance part, in other words, a buried electrode BE electrically connecting these ends, is connected to a second wiring BEN extending along the Y-axis direction. The end of the second wiring BEN is electrically connected to the second output electrode EN via a via electrode (VE3) formed thereon. The second wiring BEN is formed in the same layer as the buried electrode BE.

The resistor element (resistor R(5-2)) in the first low-resistance part RPS is connected to the buried electrode BE via a via electrode (VE), and the buried electrode BE is electrically connected to a first connection wiring WE11 continuous with the first upper electrode E11 for the first capacitor via a second via electrode (VE2).

The resistor element (resistor R(5-2)) in the second low-resistance part RNS is connected to the buried electrode BE via a via electrode (VE), and the buried electrode BE is electrically connected to a second connection wiring WE21 continuous with the second upper electrode E21 for the second capacitor via a second via electrode (VE2).

The reference electrode EG is connected to a third wiring BEG via a via electrode (VE3) arranged directly below it. The third wiring BEG is connected to a buried electrode BE located directly below one end of the resistor element R(6-2). The third wiring BEG is formed in the same layer as the buried electrode BE. The buried electrode BE connected to the third wiring BEG is electrically connected to one end of the resistor element R(6-2) via a via electrode (VE). The end of the third wiring BEG extending in the Y-axis direction is electrically connected to the first lower electrode E12 of the first capacitor C1 via a fourth wiring BEE extending in the X-axis direction. The end of the third wiring BEG is electrically connected to the second lower electrode E22 of the second capacitor C2 via a fourth wiring BEE extending in the X-axis direction.

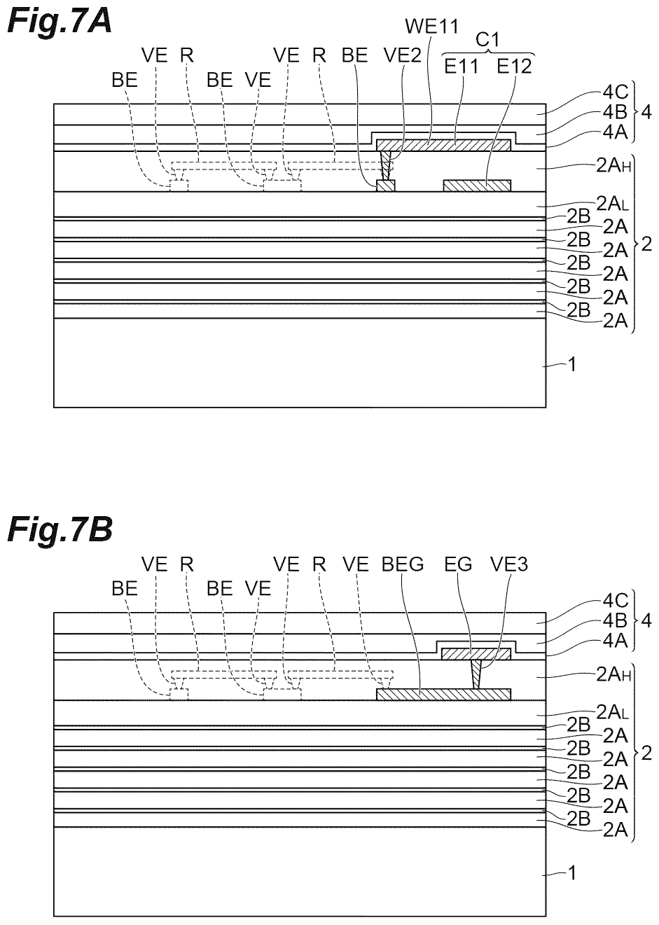

FIG. 7A is a vertical sectional view of the resistor along the arrows A-A in FIG. 6 and FIG. 7B is a vertical sectional view of the resistor along the arrows B-B in FIG. 6.

As illustrated in FIG. 7A, the semiconductor device includes an insulating layer 2 provided on a semiconductor substrate 1 and a plurality of resistors R (resistor elements, resistor layers) embedded in the insulating layer 2. All resistors R are embedded in the insulating layer 2.

The insulating layer 2 has multiple stacked dielectric layers (a first dielectric layer 2A and a second dielectric layer 2B). At least one of these dielectric layers (the first dielectric layer 2A) includes silicon oxide. At least one of these dielectric layers (the second dielectric layer 2B) includes silicon nitride. In this example, the first dielectric layer 2A and the second dielectric layer 2B are alternately stacked. The silicon oxide here is SiO₂, but the elemental ratio may be changed as needed and may contain other elements. The silicon nitride here is Si₃N₄, but the elemental ratio may be changed as needed and may contain other elements. The thickness of the insulating layer 2 may be, for example, between 5 μm and 50 μm.

The insulating layer 2 includes a lower dielectric layer 2AL formed on the second dielectric layer 2B located at the topmost position, and an upper dielectric layer 2AH formed on the lower dielectric layer 2AL. The exemplary materials of the lower dielectric layer 2AL and the upper dielectric layer 2AH are the same as the material of the first dielectric layer 2A.

The protective film 4 includes a first protective film 4A, a second protective film 4B, and a third protective film 4C, sequentially stacked on top of the insulating layer 2. As the material of the first protective film 4A, an inorganic insulating material such as silicon oxide or silicon nitride can be used, for example, SiO₂. The second protective film 4B is formed on the first protective film 4A. The material of the second protective film 4B is an inorganic insulating material such as silicon oxide or silicon nitride, and it may be the same as the material of the first protective film 4A or different, for instance, silicon nitride. The third protective film 4C is made of a resin (insulating material) such as polyimide.

A buried electrode BE is arranged directly below the resistor R, and the resistor R and the buried electrode BE are connected via a via electrode (VE). A via electrode (VE2) is provided on the buried electrode BE, and the upper end of the via electrode (VE2) is physically and electrically connected to the first connection wiring WE11 arranged on the insulating layer 2. Note that the physical connection of conductive elements involves electrical connection as well. Therefore, in the description, when the connection state is clear, the term “connection” may simply be used. The first upper electrode E11 is continuous with the first connection wiring WE11. In other words, the first upper electrode E11 constituting the first capacitor C1 is electrically connected to one end of the resistor R.

Directly below the first upper electrode E11, a first lower electrode E12 is arranged through the upper dielectric layer 2AH. The first capacitor C1 is constituted by the first upper electrode E11, the first lower electrode E12, and the upper dielectric layer 2AH interposed therebetween.

The configuration of the second capacitor C2 shown in FIG. 6 is the same as that of the first capacitor C1, and the second capacitor C2 is constituted by the second upper electrode E21, the second lower electrode E22, and the upper dielectric layer interposed therebetween. The second capacitor C2 on the second low-resistance part RNS side includes a resistor R(5) embedded in the insulating layer 2 (see FIG. 6) and a resistor R(6) embedded in the insulating layer 2 and connected in series with the resistor R(5). The second capacitor C2 on the second low-resistance part RNS side includes a second upper electrode E21 formed on the insulating layer 2 and electrically connected to one end of the resistor R(5) (see FIG. 6) and a second lower electrode E22 formed in the insulating layer 2 and electrically connected to one end of the resistor R(6) (see FIG. 6). The second lower electrode E22 is electrically connected to the resistor R(6) on the second low-resistance part RNS side and is electrically connected to the reference electrode EG formed on the insulating layer 2.

As illustrated in FIG. 7B, the reference electrode EG is arranged on the insulating layer 2. The upper end of the via electrode (VE3) is connected to the lower surface of the reference electrode EG, and the lower end of the via electrode (VE3) is connected to the third wiring BEG. The third wiring BEG functions as a buried electrode directly below the resistor R, and the resistor R and the buried electrode (the third wiring BEG) are electrically connected via a via electrode VE.

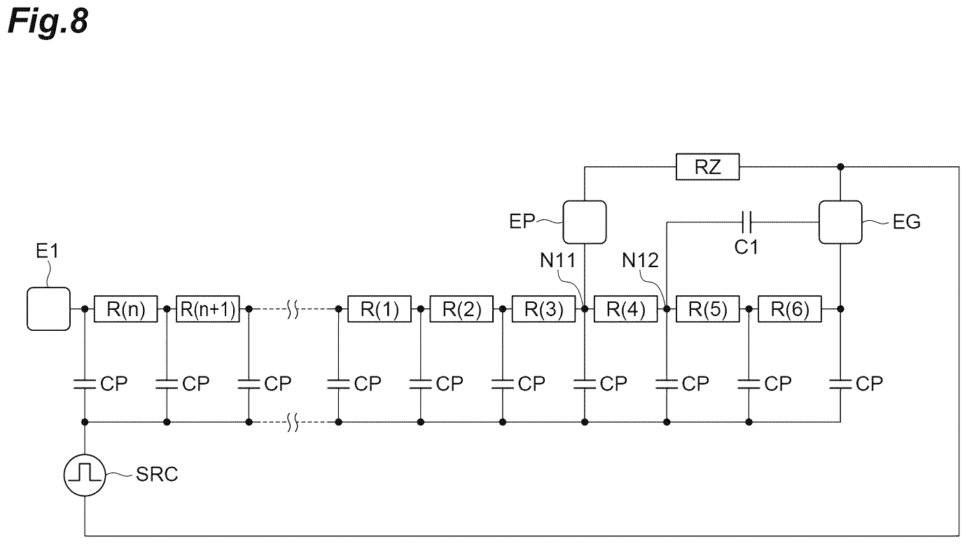

As described above, the resistor chip 10 includes a first electrode E1 formed on the insulating layer 2, a second electrode E2 formed on the insulating layer 2, a first output electrode EP formed on the insulating layer 2, and a second output electrode EN formed on the insulating layer 2. As shown in FIG. 2, the resistor chip 10 includes a first high-resistance part RP connected between the first electrode El and the first output electrode EP, a first low-resistance part RPS connected between the first output electrode EP and the reference electrode EG, a second high-resistance part RN connected between the second electrode E2 and the second output electrode EN, and a second low-resistance part RNS connected between the second output electrode EN and the reference electrode EG. The resistance value of the first high-resistance part RP is relatively higher than the resistance value of the first low-resistance part RPS, and the resistance value of the second high-resistance part RN is relatively higher than the resistance value of the second low-resistance part RNS. The first low-resistance part RPS includes the resistor R(5): RPS and the resistor R(6): RPS, and the second low-resistance part RNS includes the resistor R(5): RNS and the resistor R(6): RNS. With the above configuration, it is possible to measure the input voltage. FIG. 8 is a circuit diagram for experiments.

The resistors R(1) to R(6) described above are directly connected, and the first output electrode EP is connected to a node (N11) between the third resistor R(3) and the fourth resistor R(4). Note that the number of resistors in the high-resistance part is actually three or more, so in the figure, resistors R(n), R(n+1), and other resistors are exemplarily interposed between the first resistor R(1) and the first electrode E1. The first node N12 between the fourth resistor R(4) and the fifth resistor R(5) is connected to the reference electrode EG via the first capacitor C1. An impedance RZ (e.g., 100 kΩ) is interposed between the first output electrode EP and the reference electrode EG. The size of the electrode of the first capacitor C1 is exemplarily a square with a side of 72 μm, and in this case, the capacitance is 200 fF.

The material of the resistor R is CrSi, and a parasitic capacitance CP is interposed between it and the semiconductor substrate. The back surface of the semiconductor substrate is fixed to a frame. It is assumed that noise high frequencies such as static electricity or surge voltage are input to the semiconductor substrate via the frame. The voltage of the high-frequency source SRC is, for example, 2000 V. In this case, current flows through each resistor R via the parasitic capacitance CP. Note that the resistance values of the first resistor R(1) to the third resistor R(3) are each 400 kΩ. The resistance values of the fourth resistor R(4) to the sixth resistor R(6) are each 14.8 kΩ. Each of the fourth resistor R(4) to the sixth resistor R(6) is composed of 27 resistors (400 kΩ) connected in parallel.

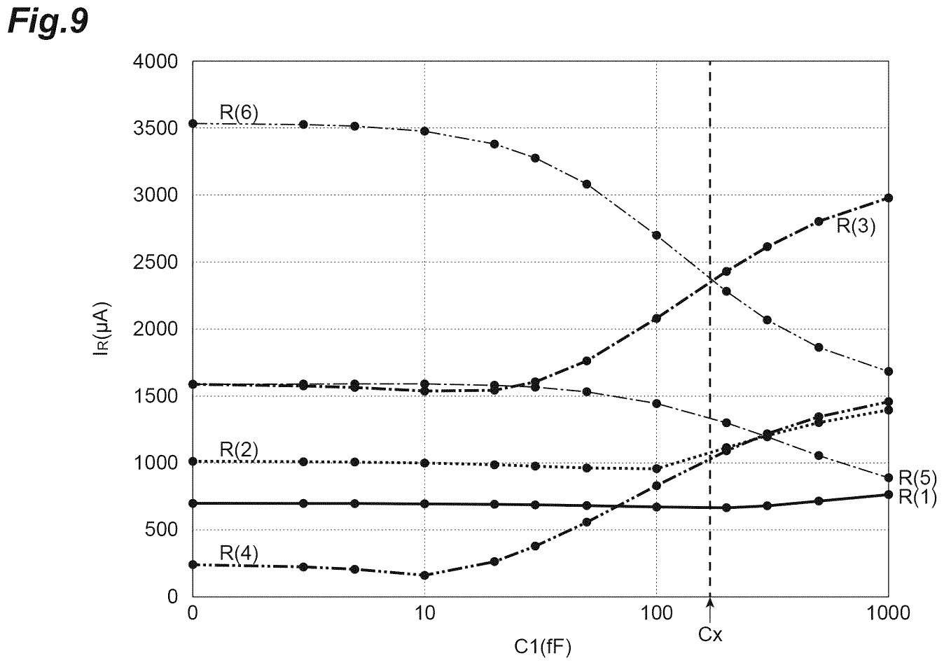

FIG. 9 is a graph showing the relationship between the capacitance (fF) of the first capacitor C1 in the circuit shown in FIG. 8 and the current I_{R} (μA) flowing through one resistor element in various resistors.

When the first capacitor C1 is absent, considering the capacitance of the first capacitor C1 (C1) as zero, the largest current IR flows through the sixth resistor R(6). This trend is the same even when dummy wiring is arranged, dummy wiring is electrically connected to the buried electrode, or dummy wiring and the buried electrode are capacitively coupled. As the capacitance of the first capacitor C1 increases, the current I_{R} in the sixth resistor R(6) decreases, and the current I_{R} in the third resistor R(3) and the fourth resistor R(4) increases. When the capacitance is Cx (fF), the current IR in the sixth resistor R(6) and the current I_{R} in the third resistor R(3) become equal. When the capacitance exceeds Cx (fF), for example, when the capacitance is 200 fF, the current IR in the sixth resistor R(6) becomes smaller than the current I_{R} in the third resistor R(3). For example, Cx (fF) is 165 fF.

From the viewpoint of increasing the withstand voltage, it is preferable to set the capacitance so that the maximum value of the current I_{R} becomes smaller. That is, if the capacitance (C1) of the first capacitor C1 is 60 fF≤C1≤500 fF, the maximum value of the current I_{R} can be made smaller than 3000 μA. If 100 fF≤C1≤300 fF, the maximum value of the current I_{R} can be further reduced.

The above structure can further include dummy wiring.

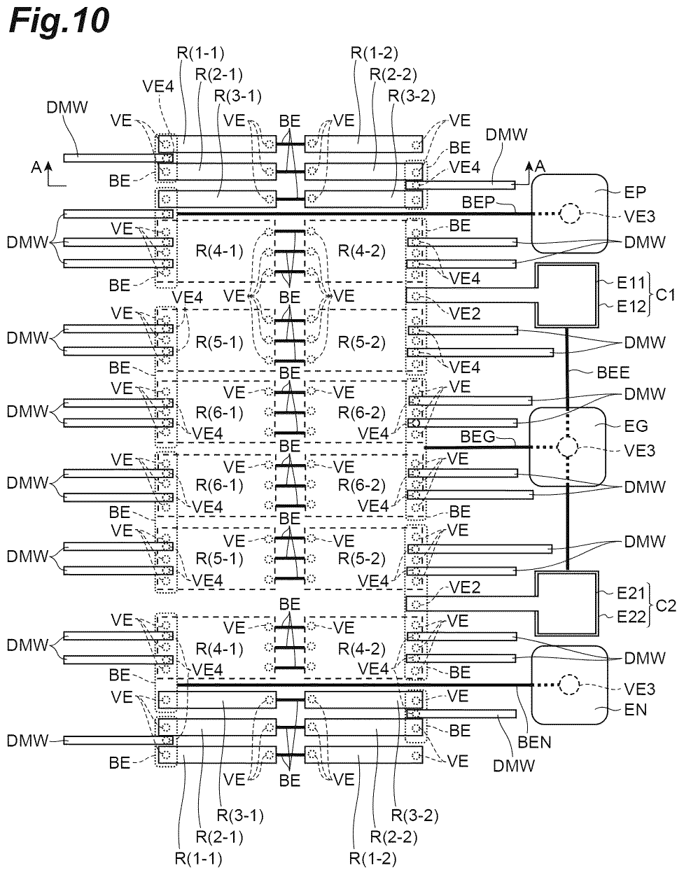

FIG. 10 is a plan view showing the configuration of a resistor with dummy wiring.

The first resistor R(1) is formed by connecting a pair of resistor elements R(1-1) and R(1-2) in series via a buried electrode BE. The resistor elements and the buried electrode BE are connected by via electrodes VE. When the resistance value of one resistor element is 200 kΩ, the series resistance value of the pair of resistor elements is 400 kΩ. When 27 resistors of 400 kΩ are connected in parallel, the resistance value is about 14.8 kΩ. The figure is a schematic diagram, and the 27 resistor elements are not shown. The number of resistor elements is arbitrary and can be determined according to the design. The fourth resistor R(4), the fifth resistor R(5), and the sixth resistor R(6) constituting the low-resistance part are resistors with resistor elements connected in parallel. The dummy wiring DMW can be connected to the buried electrode BE located directly below the gap between the parallel-connected resistor elements via a via electrode (VE4). The dummy wiring DMW may be capacitively coupled to the buried electrode BE.

The dummy wiring DMW is provided to increase the withstand voltage. When the dummy wiring DMW is present, it is possible to moderate the change in voltage per unit distance. The dummy wiring DMW is electrically connected to the buried electrode BE connecting the resistor elements via a via electrode (VE4). The dummy wiring DMW, the first output electrode EP, the reference electrode EG, the second output electrode EN, the first upper electrode E11, and the second upper electrode E21 can be formed in the same height position (same layer).

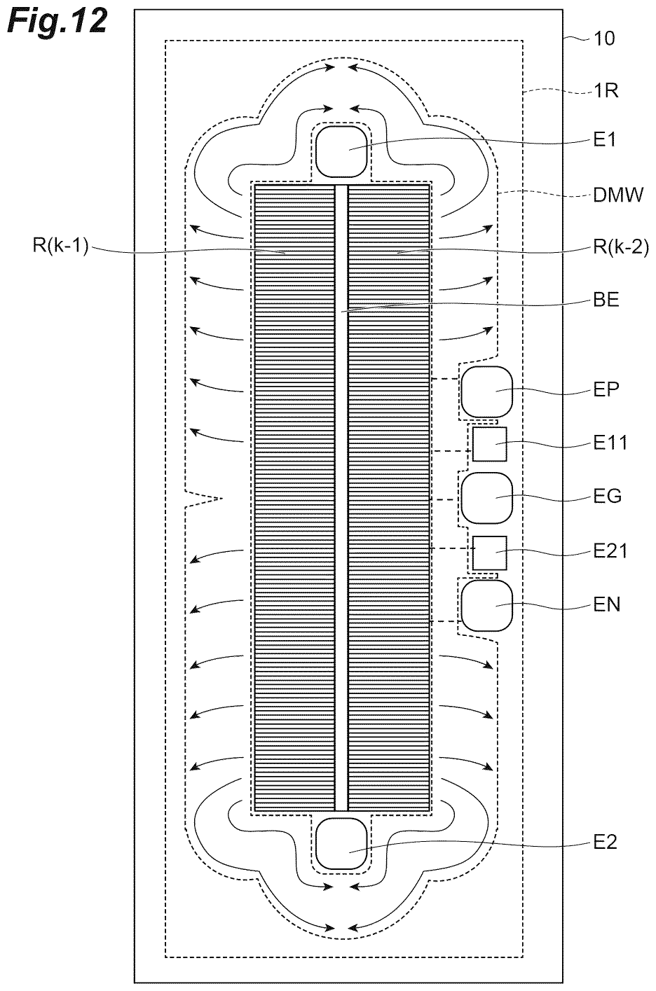

The dummy wiring DMW extends in the direction along which the individual resistor elements (resistor layers) extend but can be curved. In the vicinity of the first output electrode EP, the reference electrode EG, and the second output electrode EN, the length of the dummy wiring DMW is short. As it gets closer to the region where high voltage is applied, the length of the dummy wiring DMW becomes relatively longer and can extend to surround the first electrode E1 (second electrode E2) (see the arrow in FIG. 12).

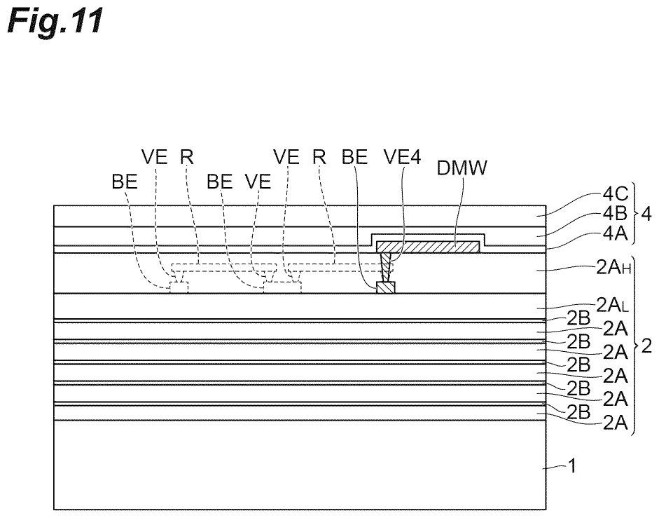

FIG. 11 is a vertical sectional view of the resistor along the arrows A-A in FIG. 10.

The resistor constituting the second resistor R(2) includes a first resistor element (R) and a second resistor element (R) connected via a central buried electrode BE and a via electrode VE. The right end buried electrode BE is connected to the right resistor element (R) via a via electrode, and the right end buried electrode BE is connected to the dummy wiring DMW via a via electrode (VE4). The connection structure of the dummy wiring DMW is the same in the cross-section including other resistors.

For example, in the fifth resistor R(5) composed of multiple resistor elements connected in parallel, one end of each of the multiple resistor elements is connected to the same buried electrode BE, and the dummy wiring DMW is connected to this buried electrode BE via a via electrode (VE4). The dummy wiring DMW is formed on the insulating layer 2 and is covered by the protective film 4. Note that the structure including the dummy wiring, the first capacitor, and the second capacitor can be applied not only to the circuit of FIG. 3A but also to the circuit of FIG. 3B.

FIG. 12 is a plan view showing an example configuration of a resistor chip 10.

This resistor chip corresponds to the circuit diagram in FIG. 3A. The resistor chip 10 is formed by creating an insulating layer on a semiconductor substrate and embedding resistors in the insulating layer. The plan shape of the resistor chip 10 is rectangular, having four sides. It is possible to embed an annular conductor 1R in the insulating layer along these sides. The annular conductor 1R may be formed from a ring of metal material such as copper; if necessary, one can provide a ring of another material (e.g., CrSi resistor material) that is electrically connected to above or below by a via electrode (e.g., tungsten). The annular body can contribute to the improvement of waterproofing and electrical stability.

A resistor is arranged between the first electrode El and the second electrode E2. The left resistor group can be R(k-1), and the right resistor group can be R(k-2). The left and right resistor groups are electrically connected by a bridge structure composed of the above-mentioned via electrodes and buried electrodes BE. The detailed structure of the resistor groups is as described above.

In the region where the dummy wiring DMW is formed, the arrow indicates the direction in which the dummy wiring extends. In the vicinity of the first output electrode EP or the second output electrode EN, the length of the dummy wiring is relatively short. In the region relatively close to the first electrode E1 or the second electrode E2, the length of the dummy wiring is longer and is arranged to surround the first electrode E1 and the second electrode E2. The dummy wiring extending from the resistor closest to the first electrode E1 is positioned to pass near the first electrode E1 because the absolute value of the potential is large. The dummy wiring extending from the resistor located slightly away from the first electrode E1 is positioned to pass slightly away from the first electrode E1 because the absolute value of the potential is smaller. In other words, due to the presence of the dummy wiring, the potential can gradually change from the first electrode E1 toward the chip edge. This can further increase the withstand voltage of the resistor chip. The dummy wiring is similarly arranged around the second electrode E2.

Note that the resistor chip 10 can also be incorporated into the amplifier chip 20 (FIG. 1).

The materials of the various components are described as follows.

The semiconductor substrate 1 (FIGS. 7A, 7B, FIG. 11) may be conductive. For example, the impurity concentration of the semiconductor substrate 1 may be greater than or equal to 5×10¹³ (cm⁻³) and less than or equal to 5×10¹⁴ (cm⁻³). The thickness of the semiconductor substrate 1 may be greater than or equal to 50 μm and less than or equal to 800 μm. Although silicon can be used as the material for the semiconductor substrate 1, a compound semiconductor such as SiC or SiGe is also possible.

The material of the resistor layer (straight-shaped resistor) constituting the resistor R has a higher resistivity than polysilicon. Specifically, the resistor (resistor layer) material includes chromium (Cr) and silicon (Si), and is CrSi, CrSiC, or CrSiN. Other materials can also be used. In other words, the resistor layer that constitutes the resistor can specifically include at least one metal compound selected from CrSi, CrSiN, CrSiO, TaN, and TiN. The resistor layer constituting the resistor can be formed by a sputtering method using a target containing the resistor material, or by other methods. Depending on the type of material used for the resistor R, a plating method can also be employed. The material of the resistor R may be composed of a single resistor material or a combination of multiple resistor materials. The thickness Rd of each resistor layer that constitutes the resistor R can be set between 1 nm and 5 nm. If the thickness Rd does not exceed the upper limit, a sufficiently high resistance can be achieved, and if it is at least the lower limit, adequate durability and strength of the resistor layer can be maintained.

Metal materials such as aluminum or copper may be used for the first electrode El, the second electrode E2, and the buried electrodes (buried wiring). Refractory metals like tungsten (W) can be used for the various via electrodes, although other electrode materials are also possible.

In the range of various parameters, when the range of any parameter P is given as Pmin≤P≤Pmax, it may be set as (Pmin+ΔP)≤P≤(Pmax−ΔP), where ΔP=(Pmax−Pmin)×R %, and R can be set to R=10, R=20, R=30, or R=40.

(Supplementary Note) As described above, various exemplary embodiments within the present disclosure may be specified as the following supplementaries:

[A1] A semiconductor device comprising: an insulating layer 2 formed on a semiconductor substrate 1; a first resistor (R(5): RPS) embedded in the insulating layer 2; a second resistor (R(6): RPS) embedded in the insulating layer 2 and connected in series with the first resistor (R(5): RPS); a first capacitor comprising: a first upper electrode E11 formed on the insulating layer 2 and electrically connected to one end of the first resistor (R(5): RPS); and a first lower electrode E12 formed in the insulating layer 2 and electrically connected to one end of the second resistor (R(6): RPS), wherein the first lower electrode E12 is electrically connected to the second resistor (R(6): RPS) and a reference electrode EG formed on the insulating layer 2.

[A2] The semiconductor device according to [A1], comprising: a third resistor (R(5): RNS) embedded in the insulating layer 2; a fourth resistor (R(6): RNS) embedded in the insulating layer 2 and connected in series with the third resistor (R(5): RNS); a second upper electrode E21 formed on the insulating layer 2 and electrically connected to one end of the third resistor (R(5): RNS); and a second lower electrode E22 formed in the insulating layer 2 and electrically connected to one end of the fourth resistor (R(6): RNS), wherein the second lower electrode E22 is electrically connected to the fourth resistor (R(6): RNS) and is electrically connected to the reference electrode EG formed on the insulating layer 2.

[A3] The semiconductor device according to [A2], comprising: a first electrode E1 formed on the insulating layer 2; a second electrode E2 formed on the insulating layer 2; a first output electrode EP formed on the insulating layer 2; a second output electrode EN formed on the insulating layer 2; a first high-resistance part RP connected between the first electrode E1 and the first output electrode EP; a first low-resistance part RPS connected between the first output electrode EP and the reference electrode EG; a second high-resistance part RN connected between the second electrode E2 and the second output electrode EN; and a second low-resistance part RNS connected between the second output electrode EN and the reference electrode EG, wherein the resistance value of the first high-resistance part RP is relatively higher than the resistance value of the first low-resistance part RPS, the resistance value of the second high-resistance part RN is relatively higher than the resistance value of the second low-resistance part RNS, the first low-resistance part RPS comprises the first resistor (R(5): RPS) and the second resistor (R(6): RPS), and the second low-resistance part RNS comprises the third resistor (R(5): RNS) and the fourth resistor (R(6): RNS).

[A4] The semiconductor device according to [A3], wherein the first resistor (R(5): RPS) comprises a plurality of resistor elements connected in parallel, wherein the second resistor (R(6): RPS) comprises a plurality of resistor elements connected in parallel, wherein the third resistor (R(5): RNS) comprises a plurality of resistor elements connected in parallel, and wherein the fourth resistor (R(6): RNS) comprises a plurality of resistor elements connected in parallel.

[A5] The semiconductor device according to [A1], wherein a capacitance of the first capacitor C1 is 60 (fF) or more and 500 (fF) or less.

[A6] The semiconductor device according to [A1], comprising: a buried electrode BE connected to the first resistor (R(5): RPS) via a first via electrode (VE); and a dummy wiring DMW formed on the insulating layer 2 and connected to the buried electrode BE via a second via electrode (VE4).

It is to be understood that not all aspects, advantages and features described herein may necessarily be achieved by, or included in, any one particular example. Indeed, having described and illustrated various examples herein, it should be apparent that other examples may be modified in arrangement and detail.

### REFERENCE SIGNS LIST

1: semiconductor substrate
1R: annular conductor
2: insulating layer
2A: first dielectric layer
2AH, 2AL: dielectric layers
2B: second dielectric layer
4: protective film
4A: first protective film
4B: second protective film
4C: third protective film
10: resistor chip
10a: first inner lead
10b: second inner lead
10c: third inner lead
10d: fourth inner lead
10e: fifth inner lead
10f: sixth inner lead
10g: seventh inner lead
10h: eighth inner lead
10i: ninth inner lead
20: amplifier chip
30: case
100: semiconductor package
110: first die pad
120: second die pad
200: battery
BE: buried electrode
BEP: first wiring
BEN: second wiring
BEG: third wiring
BEE: fourth wiring
C1: first capacitor
C2: second capacitor
DMW: dummy wiring
E1: first electrode
E2: second electrode
E11, E12: upper electrodes
E21, E22: lower electrodes
EG: reference electrode
EP: first output electrode
EN: second output electrode
R: resistor (resistor element)
RP: first high-resistance part
RN: second high-resistance part
RPS: first low-resistance part
RNS: second low-resistance part
C10: resistor circuit
C20: voltage detection circuit
CP: parasitic capacitance
D1: recess
EG1: first reference electrode
EG2: second reference electrode
GND: ground potential
HV (+): first input terminal
HV (−): second input terminal
INP: first input terminal
INN: second input terminal
N3: node
N12: first node
N22: second node
R(Dmy): dummy resistor
RN1, RN2, RP1, RP2: high-resistance parts
RZ: impedance
SRC: high-frequency source
VE: via electrode
WE11: first connection wiring
WE21: second connection wiring

What is claimed is:

1. A semiconductor device comprising:
an insulating layer formed on a semiconductor substrate;
a first resistor embedded in the insulating layer;
a second resistor embedded in the insulating layer and connected in series with the first resistor; and
a first capacitor comprising:
a first upper electrode formed on the insulating layer and electrically connected to one end of the first resistor; and
a first lower electrode formed in the insulating layer and electrically connected to one end of the second resistor,
wherein the first lower electrode is electrically connected to the second resistor and a reference electrode formed on the insulating layer.

2. The semiconductor device according to claim 1, comprising:
a third resistor embedded in the insulating layer;
a fourth resistor embedded in the insulating layer and connected in series with the third resistor; and
a second capacitor comprising:
a second upper electrode formed on the insulating layer and electrically connected to one end of the third resistor; and
a second lower electrode formed in the insulating layer and electrically connected to one end of the fourth resistor,
wherein the second lower electrode is electrically connected to the fourth resistor and is electrically connected to the reference electrode formed on the insulating layer.

3. The semiconductor device according to claim 2, comprising:
a first electrode formed on the insulating layer;
a second electrode formed on the insulating layer;
a first output electrode formed on the insulating layer;
a second output electrode formed on the insulating layer;
a first high-resistance part connected between the first electrode and the first output electrode;
a first low-resistance part connected between the first output electrode and the reference electrode;
a second high-resistance part connected between the second electrode and the second output electrode; and
a second low-resistance part connected between the second output electrode and the reference electrode,
wherein a resistance value of the first high-resistance part is relatively higher than a resistance value of the first low-resistance part, a resistance value of the second high-resistance part is relatively higher than a resistance value of the second low-resistance part, the first low-resistance part comprises the first resistor and the second resistor, and the second low-resistance part comprises the third resistor and the fourth resistor.

4. The semiconductor device according to claim 3,
wherein the first resistor comprises a plurality of resistor elements connected in parallel;
wherein the second resistor comprises a plurality of resistor elements connected in parallel;
wherein the third resistor comprises a plurality of resistor elements connected in parallel; and
wherein the fourth resistor comprises a plurality of resistor elements connected in parallel.

5. The semiconductor device according to claim 1, wherein a capacitance of the first capacitor is 60(fF) or more and 500(fF) or less.

6. The semiconductor device according to claim 1, comprising:
a buried electrode connected to the first resistor via a first via electrode; and
a dummy wiring formed on the insulating layer and connected to the buried electrode via a second via electrode.
